(19) United States
(12) Patent Application Publication
(10) Pub. No.: US 2006/0003600 A1
(43) Pub. Date: Jan. 5, 2006

(54) Contact planarization for integrated circuit processing

(76) Inventor: Chris E. Barns, Portland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/882,897

(22) Filed: Jun. 30, 2004

(51) Int. Cl. H01L 21/31; H01L 21/4763

(52) U.S. Cl. 438/780; 438/781; 438/632; 438/631; 438/626

(57) ABSTRACT

A method to form substantially planarized layers on a substrate. In an implementation, the method includes depositing a fluid material having at least one gap control bead onto a surface of the substrate, pressing a contact planarizer into the fluid material with a force sufficient to planarize at least a portion of a top surface of the fluid material, wherein the at least one gap control bead maintains a minimum thickness of the fluid material, curing the fluid material to form a substantially solid material, and separating the contact planarizer from the substantially solid material.

### TECHNICAL FIELD OF THE INVENTION

The invention generally relates to semiconductor processing, and more particularly, to methods for producing planarized layers on a semiconductor wafer.

### BACKGROUND

An essential part of the manufacturing process for integrated circuits is the planarization of materials that have been deposited on the surface of a semiconductor wafer. Two well-known techniques for planarizing materials on a semiconductor wafer are chemical mechanical polishing and the use of self-planarizing deposition materials.

Chemical mechanical polishing (CMP) is well known in the art and generally involves the use of a rotating polishing pad on a semiconductor wafer. In a CMP process, after a material is deposited on the surface of a semiconductor wafer, the polishing pad abrades the high points of the material until the material is planarized. In many cases the material is further polished by the polishing pad until the material is reduced to a predetermined thickness or until a layer of another material is exposed. Although this is a well-known and regularly used process, CMP suffers from many drawbacks. For instance, the polishing pads used to planarize the deposited materials tend to wear out or shift in their removal characteristics after multiple uses and have to be replaced. Another drawback is that a polishing pad may not polish the entire surface of the wafer in a consistent manner, thereby causing the surface of the wafer to be uneven with certain areas being overpolished and other areas being underpolished. Yet another drawback is that the CMP process may cause scratches or the shear forces damage the surface of a semiconductor wafer. Other drawbacks include difficulty in ascertaining when a predetermined thickness has been reached when polishing down a layer of material, and accidentally overexposing layers of material.

Self-planarizing materials may be applied to the surface of a semiconductor wafer using a spin-on process. As a spin-on material spreads out across the surface of the semiconductor wafer, the material attempts to settle in a somewhat planarized manner. Self-planarizing materials inherently possess physical properties that enhance the self-planarizing characteristic. Similar to CMP, however, these self-planarizing materials also suffer from some drawbacks. When a self-planarizing material is used on a semiconductor wafer that includes raised structures and valleys on its surface, the material will fill the valleys but tends to leave recessed areas above those valleys. In other words, the surface of the self-planarizing material tends to be recessed in areas where large valleys are filled. Another drawback is that this technique may only be used with materials that have the physical properties necessary for self-planarization. Materials that do not inherently possess these physical properties and processes requiring longer range planarization must use an alternate process, such as CMP.

### BRIEF DESCRIPTION OF THE DRAWINGS

FIG. 1 is a semiconductor wafer with surface structures.

FIG. 2 is a semiconductor wafer with a dielectric material and a contact planarizer.

FIGS. 3A and 3B show an implementation of a contact planarization process.

FIG. 4 is a semiconductor wafer after a contact planarization process.

FIG. 5 is a semiconductor wafer with two dielectric materials and gap control beads.

FIGS. 6A and 6B show a contact planarization process using gap control beads.

FIG. 7 is a semiconductor wafer after a contact planarization process using gap control beads.

FIGS. 8A to 8C show an implementation of a contact planarization process using a Teflon® film.

FIGS. 9A to 9C show a contact planarization process with the deposition of a film.

FIGS. 10A to 10C show a contact planarization process with the deposition of multiple films.

FIG. 11 shows a contact planarization device.

### DETAILED DESCRIPTION

Implementations of an apparatus and method to practice a contact planarization process are described herein. In the following description numerous specific details are set forth to provide a thorough understanding of the implementations. One skilled in the relevant art will recognize, however, that the techniques described herein may be practiced without one or more of the specific details, or with other methods, components, materials, etc. In other instances, well-known structures, materials, or operations are not shown or described in detail to avoid obscuring certain aspects.

The contact planarization process of the invention may be used in semiconductor wafer manufacturing, including but not limited to interconnect layers, multi chip modules, bumpless build-up layer (BBUL) and controlled collapse chip connection (C4) applications. In one implementation the contact planarization process may be used to planarize fluid materials deposited onto the surface of a semiconductor wafer, including but not limited to dielectric materials. As used herein, the term “fluid” refers to materials that easily move and change their relative position and that easily yield to pressure, in other words, materials that are capable of flowing. This includes liquids and gels, as well as some malleable solids. In further implementations, the contact planarization process may also be used to deposit one or more layers of material on a semiconductor wafer.

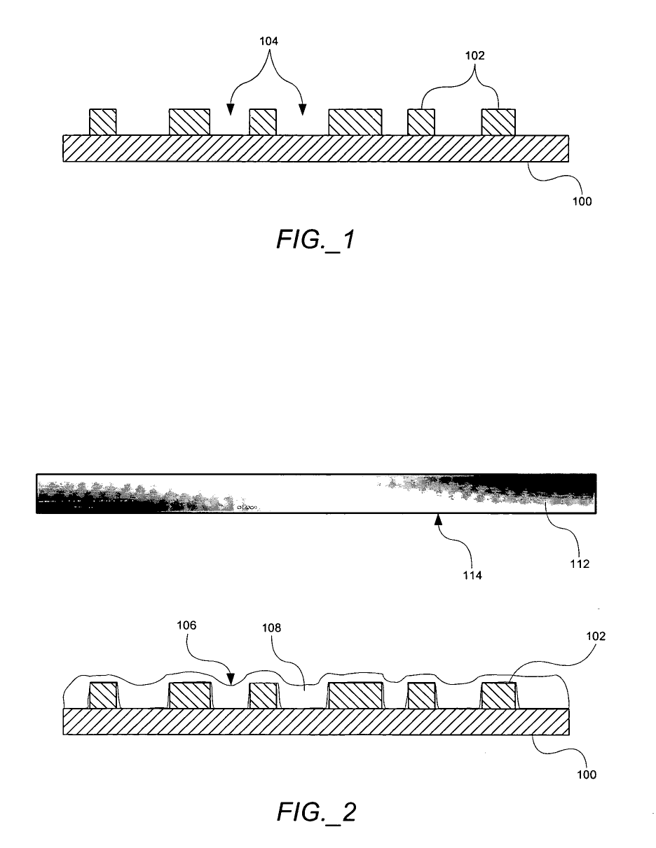

FIG. 1 is a cross-section of a portion of a semiconductor wafer 100 that includes a plurality of high topography areas 102. The semiconductor wafer 100 may include one or more layers of material that form electronic components or devices, such as transistors and interconnections. These electronic components or devices are used to form one or more integrated circuits on the semiconductor wafer 100. When the manufacturing process for the semiconductor wafer 100 is complete, the semiconductor wafer 100 may be cut into individual integrated circuit (IC) chips, where each IC chip may also be referred to as a die. The high topography areas 102 are considered part of the semiconductor wafer 100 and represent any of a variety of structures needed to build the electronic components or devices. For instance, in one implementation, the high topography areas 102 may be metal structures such as copper interconnects used in forming a controlled collapse chip connection (C4) layer. In another implementation, the high topography areas 102 may be metal components or interconnects used within one of the layers of the semiconductor wafer 100. In some implementations, if the high topography areas 102 are metal structures, they may be formed using a subtractive process, such as an aluminum deposition and etching process, or an additive process, such as a dual damascene process for copper. The gaps or spaces between adjacent high topography areas 102 are referred to herein as valleys 104.

FIG. 2 shows a deposition material 106 that has been deposited atop the semiconductor wafer 100 and the high topography areas 102. This deposition material 106 may be any material that is required in the manufacturing process for the semiconductor wafer 100, including but not limited to an insulating material, a conducting material, or a protective material. For example, the deposition material 106 may be used to fill the valleys 104 in order to insulate the high topography areas 102. The deposition material 106 may be deposited on the semiconductor wafer 100 using any of a variety of known processes, including but not limited to chemical vapor deposition, physical vapor deposition, sputtering, electroplating, spray-on and spin-on.

In accordance with the invention, the deposition material 106 is in a fluid state that allows it to be physically reshaped after it has been deposited on the semiconductor wafer 100. Alternately, the deposition material 106 may be a solid material that is subsequently treated or processed to make it a fluid material. In implementations of the invention, the deposition material 106 may also have the ability to be set or cured to form a hardened material. For instance, after the fluid deposition material 106 has been physically reshaped, a setting or curing process may be carried out to cause the deposition material 106 to harden and retain its new form. The setting or curing process may include, but is not limited to, processes such as thermoset polymerization or chemical polymerization.

In the implementation shown in FIG. 2, the deposition material 106 is a curable dielectric material 108, such as a curable low-k dielectric material. The curable dielectric material 108 is applied while it is in a fluid state that may harden upon being cured. For example, a thermal dielectric material 108 will cure upon the application of thermal energy while an ultraviolet (UV) dielectric material 108 will cure upon the application of UV radiation.

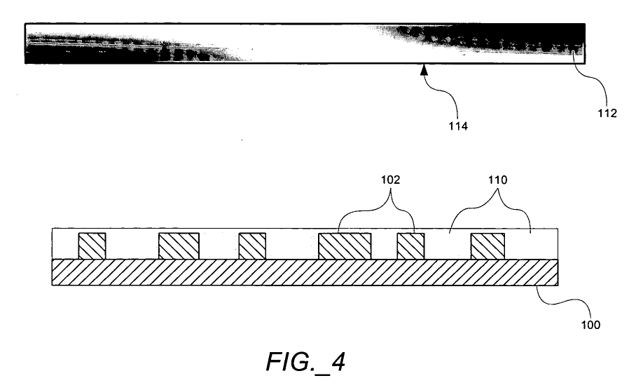

When cured, the dielectric material 108 forms a hardened dielectric layer 110 (shown in FIG. 4) that is generally used in the semiconductor wafer 100 to act as an insulator between the high topography areas 102. For instance, if the high topography areas 102 are copper wires used to interconnect components on the semiconductor wafer 100, the dielectric layer 110 can isolate the wires and reduce electrical “crosstalk” between wires that can hinder integrated circuit performance and waste power. The dielectric layer 110 may also be used between metal interconnection layers of the semiconductor wafer 100 to provide insulation.

FIG. 2 also shows a contact planarizer 112. In accordance with an implementation of the invention, the contact planarizer 112 is a structure having a substantially planar contact surface 114. The contact surface 114 is used to substantially planarize material deposited onto the semiconductor wafer 100, such as the dielectric material 108. In one implementation, the contact planarizer 112 is made from a transparent material such as glass, plastic, or another clear polymer. In another implementation, the contact planarizer 112 is made from an opaque material such as metal, Teflon®, or another opaque polymer. In yet another implementation, the contact planarizer 112 may be formed using silicon, such as a silicon wafer. The use of a silicon wafer would tend to minimize any thermal expansion mismatches. In an implementation of the invention, the silicon wafer may include a predefined topography that will imprint a pattern on a top surface of the deposition material 106 during a contact planarization process.

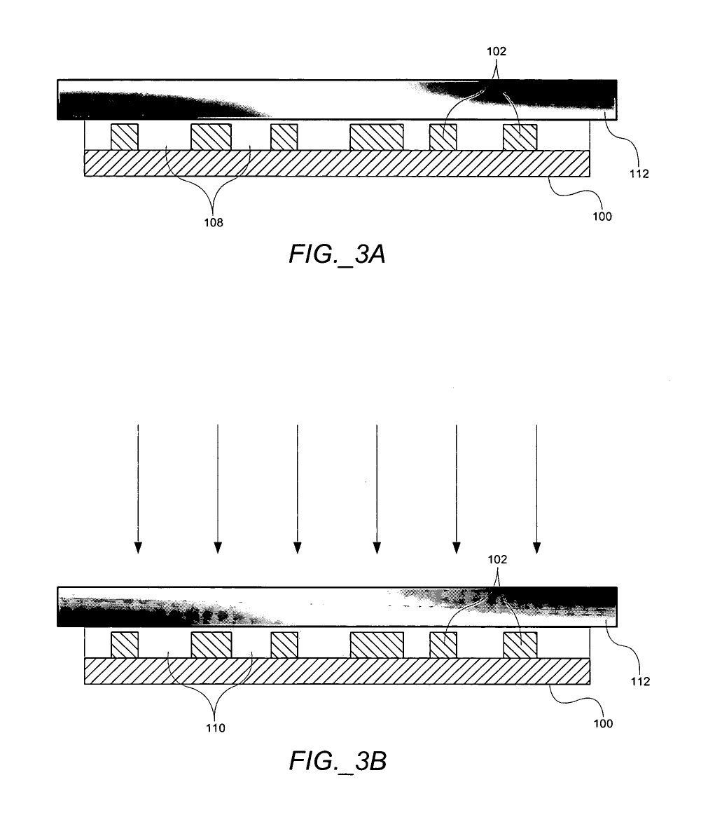

As described above, the curable dielectric material 108 may be applied to the semiconductor wafer 100 using any of a variety of deposition, CVD, dip, spray, or spin-on processes. As shown in FIG. 2, the deposition or spin-on processes generally result in a layer of dielectric material 108 that contains peaks and valleys due to the underlying high topography areas 102. In general, without the contact planarization method of the invention, these peaks and valleys will remain after the dielectric material 108 is cured, resulting in a dielectric layer that is not planar. This presents many problems when subsequent layers are built upon the dielectric layer. In another implementation, the curable dielectric material 108 may be applied to the surface of the contact planarizer 112. Thus, when the contact planarizer 112 is pressed into the semiconductor wafer 100 as described in FIGS. 3A and 3B below, the dielectric material 108 may be deposited onto the semiconductor wafer 100.

FIGS. 3A and 3B illustrate a contact planarization process according to an implementation of the invention. As shown in FIG. 3A, the contact planarizer 112 and the semiconductor wafer 100 are brought together so that the contact planarizer 112 presses on the peaks to substantially flatten the dielectric material 108. In an implementation of the invention, the semiconductor wafer 100 may be positioned face-up and the contact planarizer 112 may be pressed down into the semiconductor wafer 100. In another implementation, the semiconductor wafer 100 may be positioned face-down on top of the contact planarizer 112, and the semiconductor wafer 100 may then be pressed down into the contact planarizer 112. In implementations of the invention, one of the contact planarizer 112 or the semiconductor wafer 100 may be held stationary while the other of the contact planarizer 112 or the semiconductor wafer 100 is moved. For instance, the contact planarizer 112 may be pressed into a stationary semiconductor wafer 100 or the semiconductor wafer 100 may be pressed into a stationary contact planarizer 112. In another implementation, the semiconductor wafer 100 and the contact planarizer 112 may both be moved into one another. For clarity this description will often refer only to the contact planarizer 112 being pressed into the dielectric material 108, but it should be noted that this inherently includes implementations where the semiconductor wafer 100 is pressed into the contact planarizer 112 or where both are pressed together.

The contact planarizer 112 is generally pressed into the dielectric material 108 with a force sufficient to planarize at least a portion of the dielectric material 108. The force exerted by the contact planarizer 112 tends to cause the fluid dielectric material 108 to flow and redistribute throughout the surface of the semiconductor wafer 100 to substantially fill in the valleys 104 between the high topography areas 102. The peaks in the dielectric material 108 are pressed out so that at least a portion of the top surface of the dielectric material 108 is planarized by the contact planarizer 112.

In one implementation, the contact planarizer 112 is pressed into the dielectric material 108 until it meets a threshold level of resistance that causes it to stop; for instance, the dielectric material 108 may provide this resistance to the contact planarizer 112 once it fills the valleys 104 with material that has been pressed out from the peaks. In another implementation, the semiconductor wafer 100 or the high topography areas 102 may provide this resistance if they come into contact with the contact planarizer 112. In an implementation, a force sensor may be used to detect this threshold level of resistance and to indicate to the system that the contact planarizer 112 and the semiconductor wafer 100 should no longer be pressed together. In another implementation, the contact planarizer 112 is pressed into the dielectric material 108 with a predetermined amount of force, or a range of forces, until it can no longer overcome the resistance provided by either the dielectric material 108, the semiconductor wafer 100, or the high topography areas 102. This predetermined amount of force may be selected such that the contact planarizer 112 does not damage the semiconductor wafer 100 and the high topography areas 102 if they should come into contact.

In another implementation, a pressure and time based method may be used to press the contact planarizer 112 into the dielectric material 108. For instance, in an implementation the contact planarizer 112 can be pressed into the dielectric material at a constant force for a set amount of time. Depending on the viscosity of the dielectric material 108 and the force exerted by the contact planarizer 112, it may take anywhere from fractions of a second to hours or days for the contact planarizer 112 to redistribute the dielectric material 108 across the surface of the semiconductor wafer 100. And depending on the amount of time that the contact planarizer 112 is pressed into the dielectric material 108, the contact planarizer 112 may or may not come into contact with the semiconductor wafer 100 and the high topography areas 102. In implementations of the invention, the constant force exerted by the contact planarizer 112 on the dielectric material 108 may range from one pound per square inch (psi) to 5000 psi, and the set amount of time may range from one second to several days. In one implementation, for example, the contact planarizer 112 may be pressed into the dielectric material 108 with a force of approximately 5 psi for approximately 30 seconds.

Turning to FIG. 3B, after the contact planarizer 112 is pressed into the dielectric material 108, a setting or curing process is carried out to transform the dielectric material 108 into a cured dielectric layer 110. In one implementation, a thermally-curable dielectric material 108 is used and the arrows in FIG. 3B represent the application of thermal energy. In another implementation, a UV-curable dielectric material 108 is used and the arrows represent the application of UV radiation. In the event that UV radiation is being applied, a fully transparent or a partially transparent contact planarizer 112 must be used. After the curing process is complete, the dielectric material 108 has turned into a hardened, cured dielectric layer 110. The cure dosage during the contact does not need to be a full cure, but only enough to set the material enough to retain the planarized surface.

FIG. 4 illustrates the final step of the contact planarization process where the contact planarizer 112 is separated from the dielectric layer 110. To assist in the separation of the contact planarizer 112 from the dielectric layer 110, a mold release agent may be applied to the contact surface 114 prior to the contact planarization process. If the contact planarizer 112 is made from a material such as Teflon®, the need for a mold release agent is reduced or eliminated. As shown, the end result is a cured dielectric layer 110 that has a substantially planarized surface. The peaks and valleys created during the application of the dielectric material 108 are substantially eliminated without the need for a CMP process. The cured dielectric layer 110 is considered part of the overall semiconductor wafer 100.

A residual dielectric layer may remain over the tops of the high topography areas 102, as shown in FIG. 4. In some implementations this residual layer may not exist and in some implementations this residual layer may be substantial. The thickness of the residual layer depends on many factors. For instance, if a time and pressure based method is used to press the contact planarizer 112 into the dielectric material 108, the thickness of the residual layer may depend on the amount of force exerted by the contact planarizer 112, the amount of time this force was exerted, and the viscosity of the dielectric material 108.

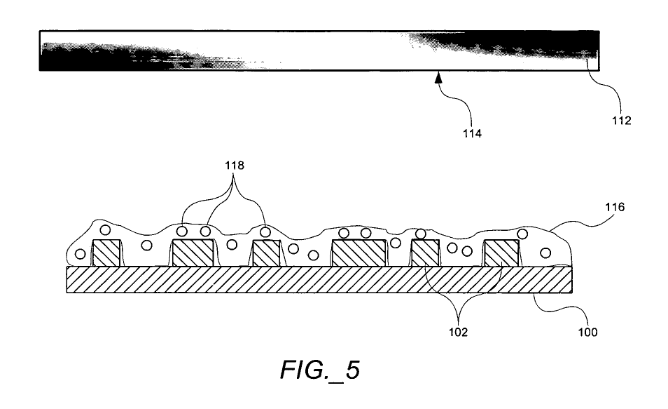

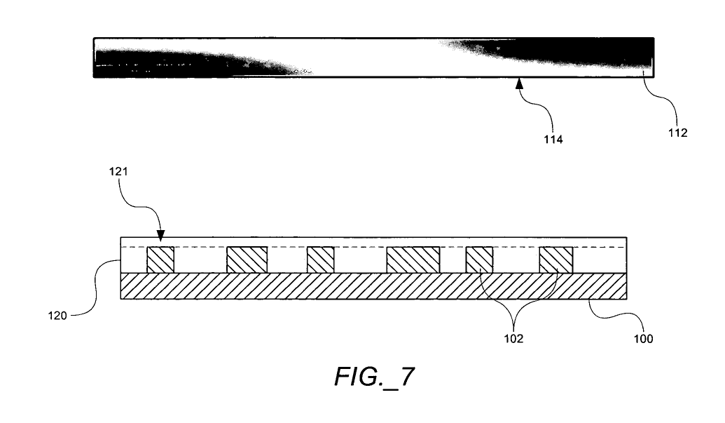

FIG. 5 illustrates another implementation of the invention where a different dielectric material 116 is deposited atop the semiconductor wafer 100 and the high topography areas 102. In this implementation, the dielectric material 116 includes one or more gap control beads 118. In one implementation of the invention, the dielectric material 116 may include a relatively low number of gap control beads 118. In another implementation, the dielectric material 116 may include a substantial number of gap control beads 118 such that the dielectric material 116 resembles a slurry. The gap control beads 118 are used to ensure that at least a minimum thickness of dielectric material remains over the high topography areas 102 when the dielectric material 116 is cured. This minimum thickness over the high topography areas 102 is shown in FIG. 7 as a cover layer 121. Unlike the residual dielectric layer that remains over the high topography areas 102 in FIG. 4, the cover layer 121 has a controlled thickness. It is the size of the gap control beads 118 that sets a minimum thickness for the cover layer 121 in regions over the high topography areas 102. Accordingly, this thickness may be controlled by choosing appropriately sized gap control beads 118 during the contact planarization process of the invention.

Similar to the dielectric material 108, the dielectric material 116 may be a conventional or a low-k dielectric material and is generally used to act as an insulator between the high topography areas 102 or between metal interconnection layers of the semiconductor wafer 100. Furthermore, this dielectric material 116 is also applied while it is in a fluid state that may harden upon being cured. In some implementations of the invention, the dielectric material 116 is made from the same dielectric as the first dielectric material 108.

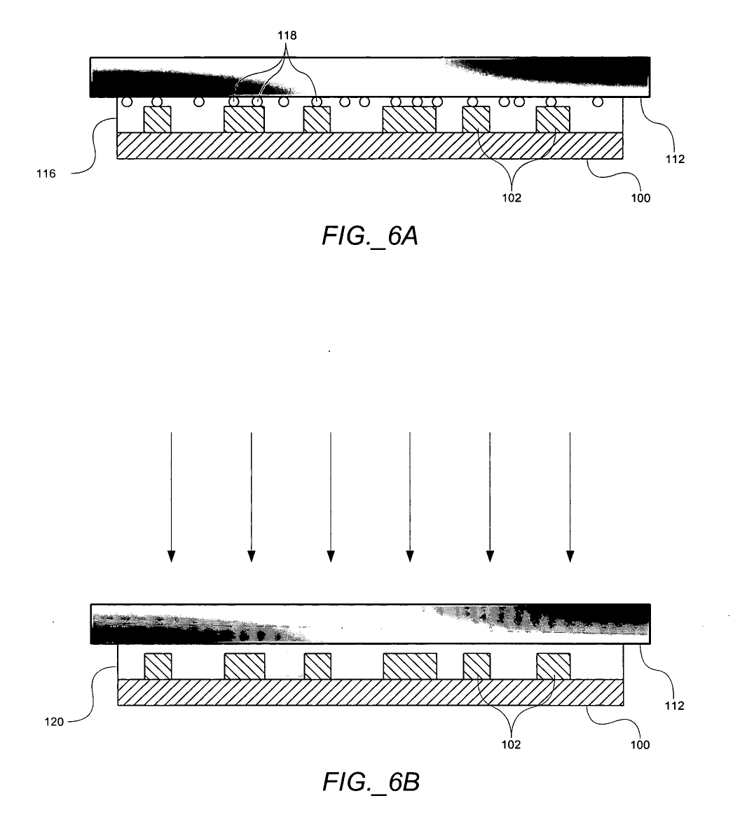

Turning to FIG. 6A, an implementation of the contact planarization process is shown in which the contact planarizer 112 and the semiconductor wafer 100 are brought together with a force sufficient to planarize at least a portion of the dielectric material 116. The contact planarization process also causes the dielectric material 116 to flow throughout the surface of the semiconductor wafer 100 and fill in the valleys 104 and any other spaces between the high topography areas 102. In an implementation, as the contact planarizer 112 is pressed into the dielectric material 116, the gap control beads 118 may become lodged between the contact planarizer 112 and the high topography areas 102, thereby preventing the contact planarizer 112 from coming into contact with the high topography areas 102. The gap between the contact planarizer 112 and the high topography areas 102 establishes a minimum thickness for the dielectric material 116 remaining over the high topography areas 102, which will form the cover layer 121 when it is cured. In an implementation where the high topography areas 102 are not present, the contact planarizer 112 is pressed into the dielectric material 116 until the gap control beads 118 become lodged between the contact planarizer 112 and the semiconductor wafer 100 itself (which includes any other surface features of the semiconductor wafer 100).

As mentioned above, in an implementation the contact planarizer 112 may be pressed into the dielectric material until it meets a threshold level of resistance that causes it to stop; that threshold level of resistance may be provided by the gap control beads 118 in this implementation. Again, in an implementation a pressure sensor may be used to detect this threshold level of resistance provided by the gap control beads 118 and to indicate to the system that the contact planarizer 112 and the semiconductor wafer 100 should no longer be pressed together. In another implementation, the mechanism being used to press the contact planarizer 112 into the dielectric material 108 may be designed to continue exerting a predetermined amount of force, or a range of forces, until it can no longer overcome the resistance provided by the gap control beads 118. This predetermined amount of force may be selected such that the contact planarizer 112 does not damage the gap control beads 118, the semiconductor wafer 100, or the high topography areas 102.

In another implementation, a pressure and time based method may be used to press the contact planarizer 112 into the dielectric material 116. As described above, the contact planarizer 112 may be pressed into the dielectric material 116 at a constant force for a set amount of time. Depending on the amount of time that the contact planarizer 112 is pressed into the dielectric material 116, the contact planarizer 112 may or may not come into contact with the gap control beads 118. But if the contact planarizer 112 does come into contact with the gap control beads 118, the gap control beads 118 will preserve the minimum thickness of dielectric material over the high topography areas 102. In implementations of the invention, the constant force exerted by the contact planarizer 112 on the dielectric material 116 may range from one pound per square inch (psi) to 5000 psi, and the set amount of time may range from one second to several days. In one implementation, for example, the contact planarizer 112 may be pressed into the dielectric material 116 with a force of approximately 5 psi for approximately 30 seconds.

In FIG. 6B, the curing process is carried out (as represented by the arrows) with either thermal energy or UV radiation being applied to the dielectric material 116. As the dielectric material 116 cures, it forms a hardened dielectric layer 120 on the semiconductor wafer 100 that includes the cover layer 121.

In one implementation of the invention, the gap control beads 118 are made from a cured dielectric material that matches the dielectric material 116. As such, when the dielectric material 116 is cured, the gap control beads 118 substantially blend into the structure of the cured dielectric material 116. In another implementation, the beads may be hollow or constructed of a different material that has a substantially lower dielectric. This implementation may result in a sealed, closed pore low-k dielectric material. In yet another implementation, the dielectric material 116 may be used in conjunction with the dielectric material 108. For instance, the dielectric material 108 may be deposited onto the semiconductor wafer 100 first, and the dielectric material 116 may be deposited on top of the dielectric material 108. This allows the dielectric material 108 to substantially fill the valleys 104 between high topography areas 102, and allows the dielectric material 116 to form the cover layer 121.

Turning to FIG. 7, after the curing process is complete, the contact planarizer 112 is separated from the final dielectric layer 120, leaving behind a hardened and substantially planar dielectric layer 120 that completely encompasses the high topography areas 102. As described above, a mold release agent may be applied to the contact surface 114 prior to the contact planarization process. Alternatively, if the contact planarizer 112 is made from a material such as Teflon®, the need for a mold release agent is reduced or eliminated. The cured dielectric layer 120 is considered part of the overall semiconductor wafer 100. The cover layer 121 is formed as part of dielectric layer 120 and may have a minimum thickness that corresponds to the size of the gap control beads 118.

In another implementation of the invention, the gap control beads 118 may be directly deposited atop the first dielectric material 108 without the need for the dielectric material 116. In this implementation, when the contact planarizer 112 and the semiconductor wafer 100 are brought together, the gap control beads 118 are pressed into the dielectric material 108 and prevent the contact planarizer 112 from coming into contact with the high topography areas 102 or the semiconductor wafer 100.

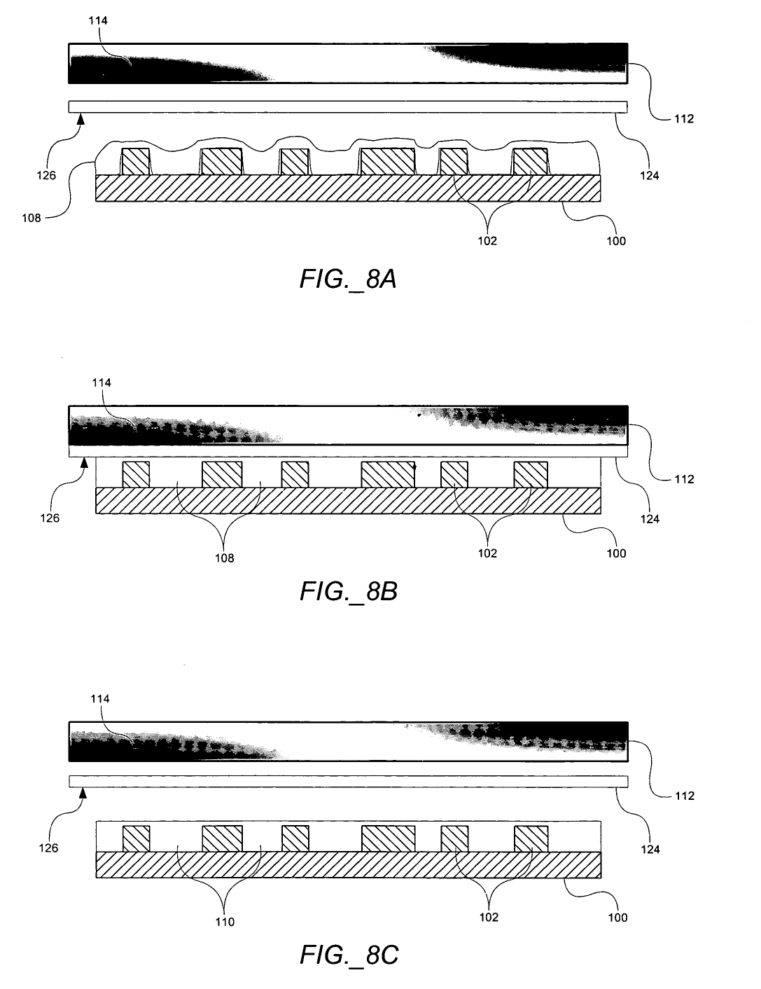

FIGS. 8A to 8C show another implementation of the invention where a non-stick film 124 is used in conjunction with the contact planarizer 112. The non-stick film 124 is formed using a material that tends to avoid becoming affixed to or bonding with the cured dielectric layer 110 or 120. In one implementation, the material used in the non-stick film 124 is Teflon®. In other implementations, alternate non-adhesive or non-stick materials may be chosen. The material used in the non-stick film 124 may be selected based on the specific material chosen for use in building the dielectric layer 110 or 120.

The non-stick film 124 includes a substantially planar surface 126 to carry out the contact planarization process and enables the contact planarizer 112 to separate cleanly from the dielectric layer 110 or 120 after the curing process. The implementation shown in FIG. 8A shows the contact planarizer 112 and the non-stick film 124 before they are pressed into the dielectric material 108. In another implementation, the non-stick film 124 may be mounted onto the contact surface 114. FIG. 8B shows the contact planarization process when the contact planarizer 112 and the non-stick film 124 are pressed into the dielectric material 108 to substantially fill the valleys 104 between the high topography areas 102 and to substantially planarize the dielectric material 108. The curing process is carried out next, and FIG. 8C shows the contact planarizer 112 and the non-stick film 124 after they have been separated from the cured dielectric layer 110. The non-stick film 124 tends to easily separate from the cured dielectric layer 110, thereby enabling the clean separation between the contact planarizer 112 and the cured dielectric layer 110. In implementations where the non-stick film 124 is mounted on the contact surface 114, the non-stick film 124 may remain substantially mounted on the contact surface 114 after the separation step. The use of the non-stick film 124 allows the separation to occur without the need for a mold-release agent. In another implementation of the invention, a mold-release agent may be used in conjunction with the non-stick film 124.

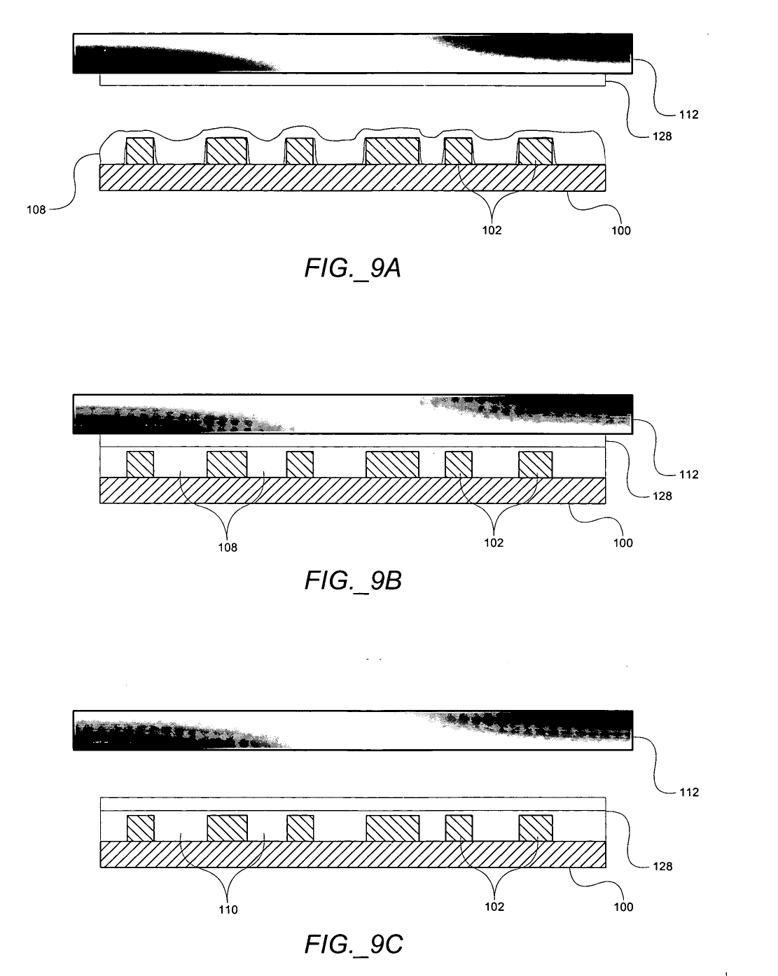

FIGS. 9A to 9C illustrate yet another implementation of the invention where the contact planarization method is used to deposit a layer of material onto the semiconductor wafer 100 in addition to planarizing the dielectric material 108. In FIG. 9A, the contact planarizer 112 includes a film 128 composed of a material that will be included as part of the semiconductor wafer 100. For instance, in one implementation the film 128 may be a film of low-k dielectric material that is being deposited atop the dielectric layer 110 and the high topography areas 102. If the film 128 is a low-k dielectric material, it may be used for many purposes such as insulating the high topography areas 102, insulating two or more metal interconnection layers, or providing an etch layer for a copper dual damascene process. In another implementation, the film 128 may be a metal layer that is being deposited to form another interconnection layer for the semiconductor wafer 100. For example, the film 128 may be an aluminum layer that is later etched to form an interconnection layer.

FIG. 9B shows the contact planarizer 112 and the film 128 being pressed into the dielectric material 108 atop the semiconductor wafer 100. The film 128 is substantially planar and presses the dielectric material 108 across the surface of the semiconductor wafer 100 to substantially fill the valleys 104 between the high topography areas 102 and to substantially planarize the top surface of the dielectric material 108. In one implementation, the film 128 becomes affixed to the dielectric layer 110 when the curing process is carried out. Curing the dielectric material 108 under the pressure exerted by the contact planarizer 112 may enhance the bonding or promote adhesion of the film 128 to the dielectric layer 110. Accordingly, when the contact planarizer 112 is separated from the semiconductor wafer 100 as shown in FIG. 9C, the film 128 remains affixed to the dielectric layer 110. In another implementation, a mold release agent is used between the contact planarizer 112 and the film 128 to better enable the film 128 to remain on the dielectric layer 110 when the contact planarizer 112 is separated from the semiconductor wafer 100. In yet another implementation, the contact planarizer 112 is made from Teflon® or includes the non-stick film 124 to enable separation from the film 128 to occur. The film 128 is considered part of the semiconductor wafer 100.

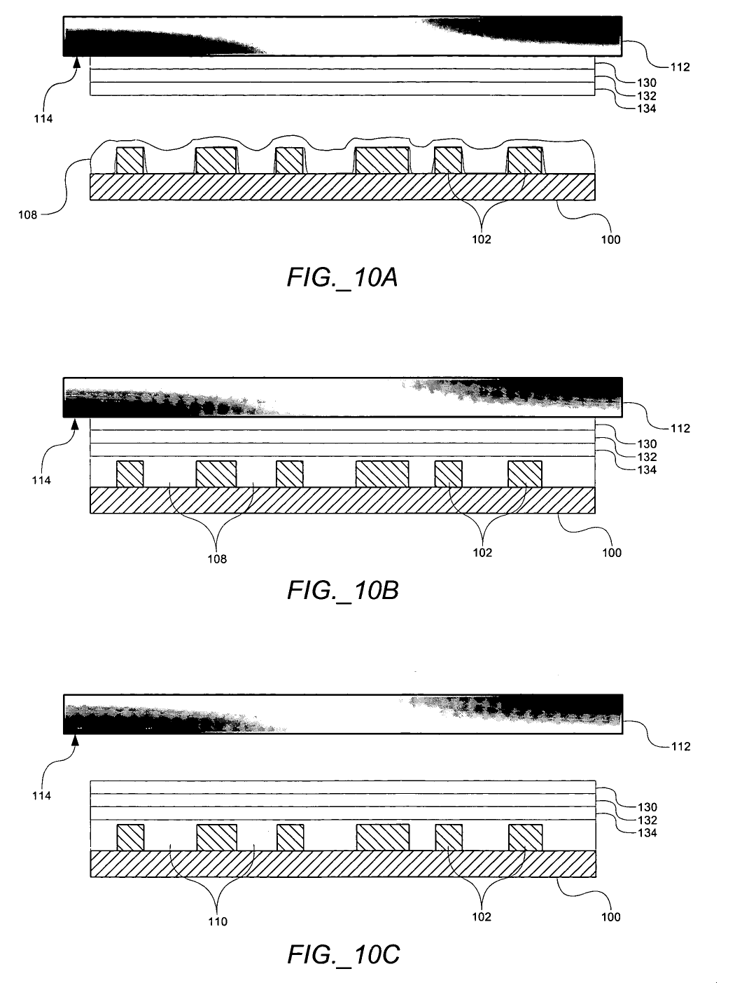

FIGS. 10A to 10C illustrate another implementation of the invention where two or more layers of material may be deposited onto the semiconductor wafer 100 during the contact planarization process. In FIG. 10A, the contact surface 114 of the contact planarizer 112 has mounted on it a first film 130, a second film 132, and a third film 134. It should be noted that any number of layers or films may be mounted onto the contact planarizer 112 depending on what is needed to complete the semiconductor wafer 100, and the use of three layers in FIG. 10A should not be construed as imposing a limitation on the invention.

Each of the first film 130, the second film 132, and the third film 134 may consist of any material that is required in the manufacturing of the semiconductor wafer 100. For instance, any of the films 130-134 may be an insulating layer, a conductive layer, a protective layer, a barrier layer, a resist layer, or an etch stop layer. Examples of such layers include, but are not limited to, dielectric films, low-k dielectric films, and metal films. In one implementation, the first film 130 and the third film 134 may be dielectric layers that insulate the second film 132, which may be a conductive layer. The first, second, or third films 130-134 may also be etched as necessary to form electrical components or interconnections.

FIG. 10B shows the contact planarization process where the contact planarizer 112 and the three films 130-134 are pressed into the dielectric material 108 to substantially planarize the material and substantially fill in the voids and valleys 104 between the high topography areas 102. The curing process is carried out next to transform the dielectric material 108 into the dielectric layer 110. Generally, the third film 134 becomes affixed to the dielectric layer 110 during the curing process. Furthermore, curing the dielectric material 108 under the pressure exerted by the contact planarizer 112 may enhance the bonding or promote adhesion of the third film 134 to the dielectric layer 110. Finally, FIG. 10C shows the contact planarizer 112 after it has been separated from the semiconductor wafer 100. The three films 130-134 remain mounted on the dielectric layer 110 and the high topography areas 102, and the three films 130-134 are considered part of the overall semiconductor wafer 100. A mold release agent may be used between the contact planarizer 112 and the first film 130 to allow for a clean separation. Alternately, the contact planarizer 112 may be made from Teflon® or the non-stick film 124 may be placed between the contact planarizer 112 and the first film 130.

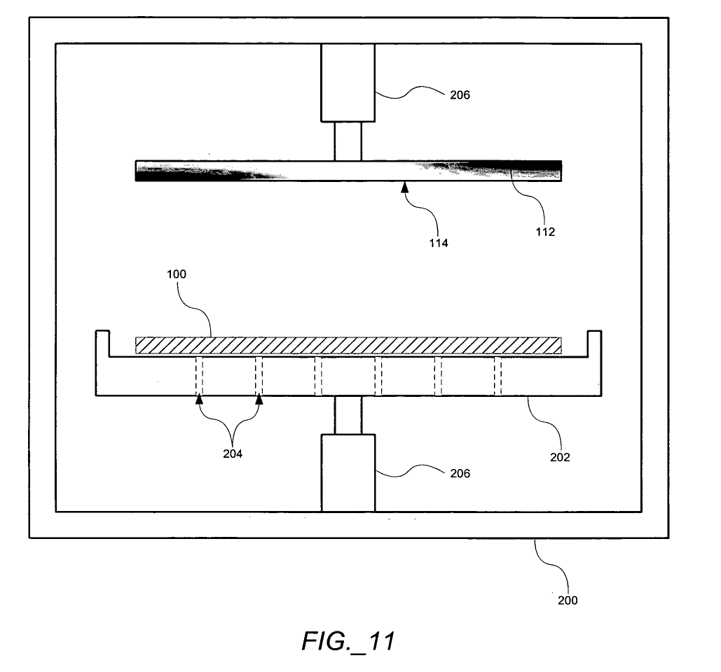

FIG. 11 illustrates one implementation of a contact planarization device 200 for carrying out the methods of the invention. The contact planarization device 200 includes a mount 202 to hold the semiconductor wafer 100 during the contact planarization process. The mount 202 may include a plurality of vacuum holes 204 that are used to secure the semiconductor wafer 100 to the mount 202. The contact planarization device 200 also includes a contact planarizer 112 that may face the semiconductor wafer 100.

The contact planarizer 112 and the mount 202 are attached to one or more mechanisms that enable the contact planarizer 112 to come into contact with the semiconductor wafer 100. In the implementation shown, one or more retractable arms 206 are used for this purpose. In other implementations, alternate mechanisms may be used to press the contact planarizer 112 and the semiconductor wafer 100 together. For example, in one implementation the mount 202 may include an inflatable film (not shown) that can press the semiconductor wafer 100 into the contact planarizer 112.

The mechanism that presses the contact planarizer 112 and the semiconductor wafer 100 together, such as the retractable arms 206, may be programmed to stop when the contact planarizer 112 meets a threshold level of resistance. For example, when the contact planarizer 112 meets resistance from the high topography areas 102 or the gap control beads 118 on the semiconductor wafer 100, the retractable arms 206 can stop pressing the contact planarizer 112 and the semiconductor wafer 100 together. The contact planarization device 200 or the retractable arms 206 may include a force sensor to determine if the contact planarizer 112 has met this threshold level of resistance. In another implementation, the process is time and pressure based and the contact planarization device 200 presses the contact planarizer 112 and the semiconductor wafer 100 together at a predetermined force for a predetermined amount of time. In some implementations of the contact planarization device 200, the contact planarizer 112 is moved and pressed into a stationary mount 202 holding the semiconductor wafer 100. In other implementations, the contact planarizer 112 is held stationary while the mount 202 presses the semiconductor wafer 100 into the contact planarizer 112.

Although not shown in FIG. 11, the contact planarization device 200 may further include devices such as a spout for dispensing the fluid deposition material 106 onto the semiconductor wafer 100, a heating element for providing thermal energy to the semiconductor wafer 100, and a UV source for providing UV radiation to the semiconductor wafer 100.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1. A method to produce a layer on a substrate comprising:
depositing a fluid material having at least one gap control bead onto a surface of the substrate;
pressing a contact planarizer into the fluid material with a force sufficient to planarize at least a portion of a top surface of the fluid material, wherein the at least one gap control bead maintains a minimum thickness of the fluid material;
setting the fluid material to form a substantially solid material; and
separating the contact planarizer from the substantially solid material.

2. The method of claim 1, wherein the fluid material comprises a dielectric material.

3. The method of claim 2, wherein the dielectric material comprises a low-k dielectric material.

4. The method of claim 1, wherein the at least one gap control bead maintains the minimum thickness of the fluid material by not allowing the fluid material to be pressed thinner than the size of the at least one gap control bead.

5. The method of claim 1, wherein the contact planarizer is pressed into the fluid material until the contact planarizer meets a threshold level of resistance from the at least one gap control bead.

6. The method of claim 1, wherein the contact planarizer is pressed into the fluid material with a predetermined amount of force for a predetermined amount of time.

7. The method of claim 6, wherein the predetermined amount of force ranges from approximately 1 psi to 10 psi.

8. The method of claim 6, wherein the predetermined amount of time ranges from approximately 1 second to 60 seconds.

9. The method of claim 2, wherein the at least one gap control bead comprises a cured bead of the dielectric material.

10. The method of claim 3, wherein the at least one gap control bead comprises a cured bead of the low-k dielectric material.

11. The method of claim 2, wherein the dielectric material is thermally curable and the setting of the fluid material comprises curing the fluid material by applying thermal energy.

12. The method of claim 2, wherein the dielectric material is UV-curable and the setting of the fluid material comprises curing the fluid material by applying UV radiation.

13. The method of claim 1, wherein the substrate comprises a semiconductor wafer that includes a plurality of high topography areas having valleys between adjacent high topography areas.

14. The method of claim 13, wherein the pressing of the contact planarizer into the fluid material distributes the fluid material over the surface of the semiconductor wafer to substantially fill one or more of the valleys.

15. The method of claim 1, further comprising placing a non-stick film between the contact planarizer and the fluid material.

16. The method of claim 1, further comprising selecting a size for the at least one gap control bead based on a desired minimum thickness of the fluid material.

17. The method of claim 5, wherein the threshold level of resistance occurs when the at least one gap control bead becomes lodged between the contact planarizer and the substrate.

18. The method of claim 5, wherein the substrate includes at least one high topography area and wherein the threshold level of resistance occurs when the at least one gap control bead becomes lodged between the contact planarizer and the at least one high topography area.

19. A method to produce a layer on a substrate comprising:
depositing a fluid material onto a surface of the substrate;
providing a planar contact surface having at least one substantially solid deposition film mounted thereon;
pressing the planar contact surface and the substantially solid deposition film into the fluid material to planarize at least a portion of a top surface of the fluid material;
curing the fluid material to form a substantially cured material and to cause the substantially solid deposition film to adhere to the substantially cured material; and
separating the planar contact surface from the substantially solid deposition film.

20. The method of claim 19, wherein the fluid material comprises a dielectric material.

21. The method of claim 20, wherein the dielectric material is thermally curable, and the curing of the fluid material comprises curing the dielectric material by applying thermal energy.

22. The method of claim 20, wherein the dielectric material is UV-curable, and the curing of the fluid material comprises curing the dielectric material by applying UV radiation.

23. The method of claim 19, wherein the planar contact surface includes a non-stick film mounted between the planar contact surface and the at least one substantially solid deposition film.

24. The method of claim 19, wherein the at least one substantially solid deposition film comprises a dielectric film.

25. The method of claim 19, wherein the at least one substantially solid deposition film comprises a low-k dielectric film.

26. The method of claim 19, wherein the at least one substantially solid deposition film comprises a metal film.

27. The method of claim 26, wherein the metal film comprises an aluminum film.

28. A method to produce a layer on a substrate comprising:
depositing a fluid conductive material onto a surface of the substrate;
pressing a contact planarizer into the fluid conductive material to planarize at least a portion of a top surface of the fluid conductive material;
setting the fluid conductive material to form a substantially solid conductive layer; and
separating the contact planarizer from the substantially solid conductive layer.

29. The method of claim 28, wherein the fluid conductive material includes at least one gap control bead to maintain a minimum thickness of the fluid conductive material by not allowing the fluid conductive material to be pressed thinner than the size of the at least one gap control bead.

30. The method of claim 28, wherein the contact planarizer is pressed into the fluid conductive material until the contact planarizer meets a threshold level of resistance.

31. The method of claim 28, wherein the contact planarizer is pressed into the fluid conductive material with a predetermined amount of force for a predetermined amount of time.

32. The method of claim 29, wherein the at least one gap control bead comprises a bead of solid conductive material.

33. The method of claim 28, wherein the substrate comprises a semiconductor wafer that includes a plurality of high topography areas having valleys between adjacent high topography areas.

34. The method of claim 33, wherein the pressing of the contact planarizer into the fluid conductive material distributes the fluid conductive material over the surface of the semiconductor wafer to substantially fill one or more of the valleys.

35. A method to produce a planarized dielectric layer on a substrate comprising:
depositing a fluid dielectric material onto a surface of the substrate;
pressing a contact planarizer directly into the fluid dielectric material to planarize at least a portion of a top surface of the fluid dielectric material;
setting the fluid dielectric material to form a substantially solid dielectric layer; and
separating the contact planarizer from the solid dielectric layer.

36. The method of claim 35, wherein the fluid dielectric material is thermally curable and the setting of the fluid dielectric material comprises curing the fluid dielectric material by applying thermal energy.

37. The method of claim 35, wherein the fluid dielectric material is UV-curable and the setting of the fluid dielectric material comprises curing the fluid dielectric material by applying UV radiation.

38. The method of claim 37, wherein the contact planarizer is substantially transparent.

39. The method of claim 38, wherein the UV radiation is applied through the substantially transparent contact planarizer.

40. A method to produce a layer on a substrate comprising:
depositing a fluid material having at least one gap control bead onto a surface of a contact planarizer;
pressing the contact planarizer into the substrate to deposit the fluid material onto the substrate with a force sufficient to cause the fluid material to fill one or more valleys present on the surface of the substrate, wherein the at least one gap control bead maintains a minimum thickness of the fluid material;
setting the fluid material to form a substantially solid material; and
separating the contact planarizer from the substantially solid material.

41. The method of claim 40, wherein the fluid material comprises a dielectric material.

42. The method of claim 40, wherein the gap control bead comprises a cured dielectric material.

43. The method of claim 40, wherein the at least one gap control bead maintains the minimum thickness of the fluid material by not allowing the fluid material to be pressed thinner than the size of the at least one gap control bead.

44. A method to produce a layer on a substrate comprising:
depositing a fluid material onto a surface of the substrate;
providing a contact planarizer having a contact surface that includes a predefined topography;
pressing the contact planarizer into the fluid material to imprint the predefined topography into a top surface of the fluid material;
setting the fluid material to form a substantially solid topography layer; and
separating the contact planarizer from the substantially solid topography layer.

45. The method of claim 44, wherein the fluid material is a dielectric material.

46. The method of claim 45, wherein the topography layer defines trenches that can be used in a copper dual damascene process.

47. The method of claim 44, wherein the fluid material is a conductive material.

48. The method of claim 47, wherein the topography layer defines electrical interconnections.

49. A method to produce a layer on a substrate comprising:
providing a planar contact surface having at least one substantially solid deposition film mounted thereon;
depositing a fluid material onto a surface of the substantially solid deposition film;
pressing the substrate into the planar contact surface and the substantially solid deposition film to deposit the fluid material onto the substrate with a force sufficient to cause the fluid material to fill one or more valleys present on the surface of the substrate;
curing the fluid material to form a substantially cured material and to cause the substantially solid deposition film to adhere to the substantially cured material; and
separating the planar contact surface from the substantially solid deposition film.

50. The method of claim 49, wherein the at least one substantially solid deposition film comprises a dielectric film.

51. The method of claim 49, wherein the at least one substantially solid deposition film comprises a low-k dielectric film.

52. The method of claim 49, wherein the at least one substantially solid deposition film comprises a metal film.

53. The method of claim 49, wherein one or more air gaps are left within one or more of the valleys.
